(19) United States
(12) Patent Application Publication
(10) Pub. No.: US 2020/0021254 A1
(43) Pub. Date: Jan. 16, 2020

(54) LOW NOISE AMPLIFIER WITH IMPROVED ABSOLUTE MAXIMUM RATING PERFORMANCE

(71) Applicant: FCI INC., Seongnam-si (KR)

(72) Inventors: Hwa Hyeong SHIN, Seongnam-si (KR); Hyun Chul SHIM, Seongnam-si (KR)

(21) Appl. No.: 16/512,421

(22) Filed: Jul. 16, 2019

(30) Foreign Application Priority Data
Jul. 16, 2018 (KR) 10-2018-0082229

(51) Int. Cl. H03F 3/185; H03F 3/21; H03F 1/02; H03H 7/38

(52) U.S. Cl. CPC H03F 3/185; H03H 7/38; H03F 1/0211; H03F 3/21

(57) ABSTRACT

The present disclosure provides a low noise amplifier with improved absolute maximum rating performance. The low noise amplifier with improved absolute maximum rating performance includes at least one transistor utilized to amplify a input signal externally inputted through an input line of the low noise amplifier; a bias unit connected to the input line and configured to set a driving condition of the transistor; impedance matching unit configured to match an impedance of the low noise amplifier; a blocking capacitor connected to the input line and configured to block a direct current of the input signal; and a first diode unit connected to a first end of the transistor and a second end of the transistor. The first diode unit is configured to adjust a voltage between the first end of the transistor and the second end of the transistor under a first standard voltage.

### FIELD OF INVENTION

The present disclosure relates to a low noise amplifier and, more particularly, relates to a low noise amplifier with improved absolute maximum rating performance. That is, simply changing structure of current low noise amplifiers to adjust the voltage between the transistor terminals of the low noise amplifier so that transistors are driven within their own maximum rating performance. Therefore, stability and durability of the low noise amplifier are improved and amplifying functions can be performed more accurately.

### BACKGROUND OF INVENTION

The content described in this section merely provides background information, instead of prior art, of the present disclosure.

When utilized in wireless high-frequency signal fields, radio frequency (RF) signals have characteristics of not being restricted by space which can satisfy user mobility. Thus, RF signals are widely applied in various fields such as wireless communication, mobile communication, and data transmission and reception, etc.

FIG. 1 illustrates a structural diagram of a RF signal transceiver system. As shown in FIG. 1, RF transceiver system can be roughly divided into a transmit unit Tx for transmitting RF signals and a receiver unit Rx for receiving RF signals from various sources.

Power amplifier of the transmit unit Tx amplifies the RF signals in order to sufficiently transmit RF signals to a distant receiver unit Rx. A switch SW of the receiver unit Rx distributes the RF signals to downstream devices. A filter of the receiver unit Rx filters the signals to allow only signals which have appropriate frequency band to be transmitted to each downstream device.

The low noise amplifier LNA as shown in FIG. 1 amplifies received RF signals and filters noise of the received RF signals.

The power amplifier PA makes the RF signals be sufficiently amplified for making successful transmission. Signal attenuations may occur during wireless RF signals transmission. The characteristics of the wireless transmissions results various types of noise during RF signals transmission. Therefore, most RF transceiver systems must have components for removing noise in the RF signals and noise generated by the switch SW. and RF transceiver systems must have filters during the compensations and transmissions for reducing signal attenuations.

On the other hand, dual-frequency terminals that provide multiple communication frequency bands in a single terminal have become more and more popular. With the rapidly development of wireless communication, dual-frequency terminals providing multiple communication frequency bands are utilized to improve the applicability of wireless communication terminals in so that terminals can select communication frequency according to environments. The communication frequency is selectively determined in accordance with changes in the communication environment, thereby stable communication is ensured.

However, the dual-frequency terminals require building in low noise amplifiers for wireless communication which cause affections.

For example, in order to support frequency bands of long term evolution (LTE) and second generation (2G) at the same time, when installing a 2G (including GSM/EDGE/PCS/DCS) transceiver, LTE terminals can transmit 2G RF signals with power over 35 dBm to another terminal through an antenna. Therefore, the stability and durability of the low noise amplifier are affected.

Voltages and current provided while using semiconductor devices with low noise amplifiers should not affect the stabilities of electronic devices. That is, voltages or current provided to the electronic devices should be within absolute maximum rating value. However, if power of signals received by the dual-frequency terminals increases, voltages and current applied to transistor of the low noise amplifier will exceed absolute maximum rating value.

In this situation, if directly applying low noise amplifier having lower absolute maximum rating to dual-frequency terminals, inputting overloaded current or overloaded voltages will cause heavy burden for internal components (such as transistors) of low noise amplifiers. As a result, safety and durability of device become worse or characteristics of devices have changed.

In addition, accuracies of low noise amplifiers decline because characteristics of devices have changed or qualities of devices are worsen. Overloading in a long time makes life periods of low noise amplifiers become shorter. Therefore, low noise amplifiers have to be replaced frequently. As a result, maintaining costs of low noise amplifiers and receiver unit Rx increase.

These problems appear on not only a single terminal performing dual-frequency, but also multiple terminals in one system, such as security system utilizing multiple terminals or multiple terminals locate close to each other.

Hence, for solving the above-mentioned problems, a low noise amplifier is required to restrict the power of RF signals inputted to the low noise amplifier (or transistor built in) within the absolute maximum rating of the low noise amplifier (or the transistor built in).

### SUMMARY OF INVENTION

An object of an embodiment of the present disclosure is providing a device that restricts a voltage applied to being below a low noise amplifier to a maximum rating voltage by utilizing a diode or an additional component even increases the input power. As a result, the stability and durability of the transistor and the low noise amplifier can be improved.

According to an embodiment of the present disclosure, the present disclosure provides a low noise amplifier with improved absolute maximum rating performance includes: at least one transistor utilized to amplify a input signal externally inputted through an input line of the low noise amplifier; a bias unit connected to the input line and configured to set a driving condition of the transistor; impedance matching unit configured to match an impedance of the low noise amplifier; a blocking capacitor connected to the input line and configured to block a direct current of the input signal; and a first diode unit connected to a first end of the transistor and a second end of the transistor. The first diode unit is configured to adjust a voltage between the first end of the transistor and the second end of the transistor under a first standard voltage.

According to an embodiment of the present disclosure, even the voltage applied on the low noise amplifier increases, the voltage applied to the low noise amplifier is restricted to being below an absolute maximum rating voltage that is, below a breakdown voltage, by utilizing a diode or an additional component. The stability and durability of the transistor and the low noise amplifier can be improved.

Moreover, according to an embodiment of the present disclosure, the stability and durability of the transistor and the low noise amplifier are improved. The transistor and the low noise amplifier can be more accurately and precisely amplified to drive, the lifetimes of the low noise amplifier or the transistor are prolonged. As a result, cost and time of replacement and maintenance is reduced.

### DESCRIPTION OF DRAWINGS

FIG. 1 illustrates a structure of radio frequency of a transceiver system.

FIG. 2 and FIG. 3 illustrate a circuit of a low noise amplifier utilizing a diode to adjust a voltage applied to a bipolar transistor of a first embodiment of the present disclosure.

FIG. 4 and FIG. 5 illustrate a circuit of the low noise amplifier utilizing a diode to adjust a voltage applied to a field effect transistor of a second embodiment of the present disclosure.

FIG. 6 and FIG. 7 illustrate simulation results regarding input powers of voltages applied to the bipolar transistor in FIG. 2.

FIG. 8 and FIG. 9 illustrate a circuit of the low noise amplifier utilizing a second adjusting unit consist of components other than diode to adjust a voltage applied to a field effect transistor of a third embodiment of the present disclosure.

FIG. 10 illustrates simulation results of the second adjusting unit in FIG. 8 and FIG. 9.

FIG. 11 illustrates simulation results regarding voltages applied to the bipolar transistor based on the low noise amplifier according to FIG. 8 and FIG. 9.

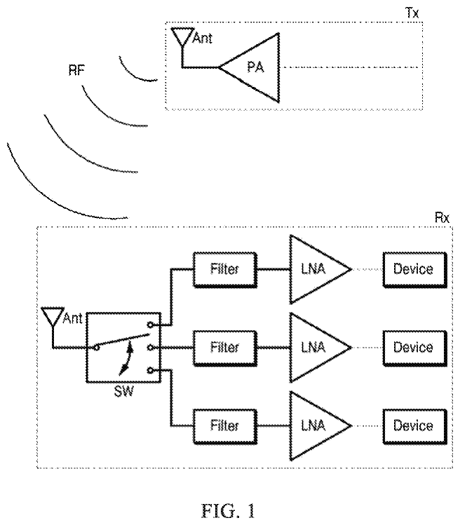

### DETAILED DESCRIPTION OF PREFERRED EMBODIMENTS

Hereinafter, some embodiments of the present disclosure will be described in detail with exemplary drawings. The same structural elements are given the same reference numbers even if they appear in different drawings. Detailed descriptions of related well-known structures or functions will be omitted in the present disclosure.

In the present disclosure, the terms such as first, second, A, B, (a), (b), etc., may be used for distinguishing different structural elements instead of limiting substantial order structural elements. In the specification, when a component is “included” or “having” other structural elements, unless specified or limited, the component is not excluded other structural elements and may include other structural elements. Further, the terms “part”, “module” in the specification mean a unit that processes at least one function or action, which may be implemented as hardware or software or a combination of hardware and software.

As described above, the low noise amplifier with improved absolute maximum rating performance circuit 100 of the present disclosure disposes a diode or a second adjusting unit 180 in the conventional low noise amplifier for adjusting voltages between the terminals of the transistor 110 so that the voltages applied to the transistor 110 are suitable for the target and application of the low noise amplifier 100 or suitable for the compatibility between the low noise amplifier 100 and devices disposed at the front end or the back end of the low noise amplifier 100. As a result, even if applying radio frequency (RF) signals having higher power to the transistor 110, the voltage between the terminals is restricted or limited within the absolute maximum rating voltage.

The transistor 110 is capable of various functions such as switching and amplifying. The low noise amplifier 100 of the present disclosure uses the characteristics of the transistor 110 to implement amplifying input voltages or current.

The transistor 110 of the present disclosure can be a bipolar junction transistor (BJT) 113 or a field effect transistor (FET) 115 or any other transistors can implement amplifying input voltages or input current. The followings description take the transistor 110 is BJT 113 as the first embodiment and then take the transistor 110 is the FET 115 as the second embodiment.

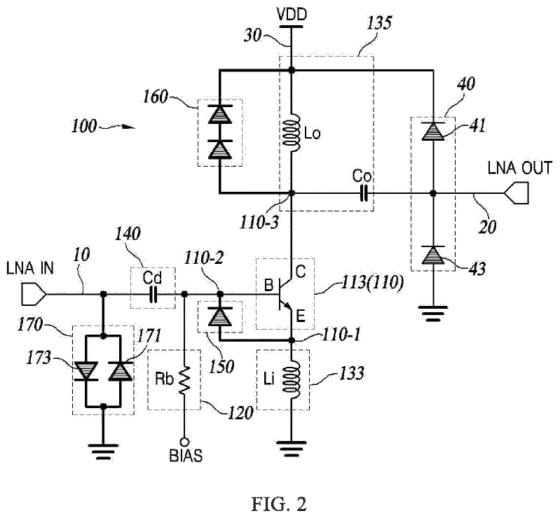

FIG. 2 illustrates the low noise amplifier 100 of the present disclosure which uses diode for adjusting voltages applied to the terminals of the BJT 113. The following description illustrates the low noise amplifier 100 having the BJT 113 of a first embodiment of the present disclosure.

As shown in FIG. 2, the low noise amplifier 100 of the present disclosure includes the BJT 113, a bias unit 120, an impedance matching unit 130, a blocking capacitor 140, and a first diode unit 150.

As shown in FIG. 2, an input signal is connected to the BJT 113 of the low noise amplifier 100 of the first embodiment through an input line 10. The low noise amplifier 100 amplifies alternating signals inputted though the input line 10 and outputs amplified signals through an outputting line 20. Preferably, the alternating signals are alternating current or alternating voltages.

The BJT 113 can be a common-emitter (CE) amplifier, a common-base (CB) amplifier, or a common-collector (CC) amplifier. The BJT 113 includes an emitter junction, a base junction, and a collector junction who are connected to a ground GND, the input line 10, and the outputting line 20, respectively.

The BJT 113 in FIG. 2 is a CE amplifier. However, the BJT 113 of the present disclosure can be a CB amplifier, a CC amplifier, or other kinds of BJTs if amplifying functions can be implemented.

The BJT 113 of the present disclosure is a CE amplifier. As shown in FIG. 2, the base of the BJT 113 is connected with the input line 10 of the low noise amplifier 100. The collector of the BJT 113 is connected with a driving power line 30 and the outputting line 20. The driving power line 30 is utilized to provide driving power of the low noise amplifier 100. The emitter of the BJT 113 is connected with the ground GND.

As mentioned above, the amplifier of the low noise amplifier 100 can be a BJT 113 and FET 115. When the amplifier of the low noise amplifier 100 is BJT 113, a first end 110-1, a second end 110-2, and a third end 110-3 of the BJT 113 are emitter, base and collector of the BJT 113 respectively. When the amplifier of the low noise amplifier 100 is FET115, the first end 110-1, the second end 110-2, and the third end 110-3 of the FET 115 are source, gate and drain of the FET 115 respectively.

As shown in FIG. 2, the bias unit 120 is connected with the input line 10 of the low noise amplifier 100 for multiplying voltages on inputted alternating RF signals in the purpose of setting driving point (so-called Q-point) or working point of the BJT 113. Thus, the BJT 113 can perform as an amplifier when voltages applied to the BJT 113 become forward bias.

The bias unit 120 illustrated in FIG. 2 consists of single impedance R_{b}. However, if the Q-point of the BJT 113 can be set properly when implementing amplifying functions, the bias unit 120 can consist of several impedances for distributing proper voltages applied to the BJT 113.

The bias unit 120 can further includes a capacitor paralleling with the impedance R_{b}. The capacitor is connected between the second end 110-2 and the ground GND. The capacitor and impedance R_{b} in this structure can implement low pass filter functions. Hence, noise applied to the bias unit 120 can be eliminated.

As shown in FIG. 2, the impedance matching unit 130 includes an input impedance matching unit 133 and an output impedance matching unit 135. The input impedance matching unit 133 can make the impedance outputted by front end devices of the low noise amplifier 100 and the impedance of the low noise amplifier 100 match each other. Therefore, maximum power transmitted by the front end devices can be delivered to the low noise amplifier 100 of the present disclosure.

The output impedance matching unit 135 can make the impedance inputted to back end devices of the low noise amplifier 100 and the impedance of the low noise amplifier 100 match each other. Therefore, maximum power transmitted by the low noise amplifier 100 can be delivered to the back end devices.

The input impedance matching unit 133 and output impedance matching unit 135 are not limited by FIG. 2. The input impedance matching unit 133 and output impedance matching unit 135 can consist of a single impedance, capacitor, inductor, or combination of impedance, capacitor, and/or inductor.

Preferably, as shown in FIG. 2, the output impedance matching unit 135 of the present disclosure consists of an inductor L₀ and a capacitor C₀ in parallel for producing resonance.

Particularly, the output impedance matching unit 135, consisting of the inductor L₀ and the capacitor C₀, can resonate a driving frequency of back end devices connected with the low noise amplifier 100. The signals amplified by the BJT 113 having the same frequency as the driving frequency will be filtered by the resonance. By utilizing the output impedance matching unit 135, only signals at frequencies corresponding to the working frequencies of back end devices will be output to those back end devices.

The blocking capacitor 140 of the present disclosure blocks direct current of the signals transmitted through the input line 10. Only alternating current of the signals will be supplied to the BJT 113.

As shown in FIG. 2, the low noise amplifier 100 of the present disclosure further includes an electrostatic discharge (ESD) diode 40. When the ESD diode 40 applies overloaded voltages to the outputting line 20, the overloaded voltages will be discharged to the driving power line 30 or the ground GND because current flowing through the diode only can flow forward due to the characteristic of diodes.

The following description illustrates discharging overloaded voltages applied to the input line 10 to ground GND by utilizing a third diode unit 170.

As shown in FIG. 2, the low noise amplifier 100 of the present disclosure is common-emitter amplifier. The first end 110-1 and the second end 110-2 of the BJT 113 are emitter and base of BJT 113. The first diode unit 150 of the present disclosure adjusts or restricts the voltages between the emitter 110-1 and the base 110-2 within a first standard voltage by utilizing characteristics of diodes.

As shown in FIG. 2, the first diode unit 150 of the present disclosure is connected between the emitter 110-1 and the base 110-2. The first standard voltage can be set according to the application requirements of the low noise amplifier 100, the absolute maximum rating voltages, and other requirements. Hence, the numbers of diode in the first diode unit 150 and the structure of the first diode unit 150 can be adjusted according to the first standard voltage.

For example, the breakdown voltage between the emitter 110-1 and base 110-2 is 1 V, thus, the peak of the first standard voltage between the emitter 110-1 and base 110-2 is restricted under the breakdown voltage 1 V. As shown in FIG. 2, the first diode unit 150 can consist of a single diode connected between the emitter 110-1 and base 110-2.

When the peak of the first standard voltage between the emitter 110-1 and base 110-2 is restrict under a breakdown voltage 2 V, The first diode unit 150 consist of two diodes connected between the emitter 110-1 and base 110-2.

When the peak of the first standard voltage between the emitter 110-1 and base 110-2 is restrict in a specific scope, the first diode unit 150 of the present disclosure can be the third diode unit 170 consist of two back-to back diodes as shown in FIG. 2.

In various structure of the first diode unit 150 of the present disclosure, when the voltage difference between the emitter 110-1 and base 110-2 higher than the first standard voltage, the first diode unit 150 of the present disclosure has forward bias voltage.

Therefore, current flows from the emitter 110-1 to the case 110-2 through the first diode unit 150 so that the voltages difference between the emitter 110-1 and base 110-2 is restricted within the first standard voltage.

By utilizing the above-mentioned to simply modify circuit design, the diode disposed between two terminals of the BJT 113 of the low noise amplifier 100 of the present disclosure can restrict or adjust voltages applied to the BJT 113. This simple structure can reduce manufacture cost and manufacture duration.

By utilizing the above-mentioned to simply modify circuit design, the voltages applied to the BJT 113 can be restricted within the absolute maximum rating voltage. Therefore, the stability and durability of the low noise amplifier 100 are improved and accuracy is assured.

According to application, the low noise amplifier 100 of the present disclosure can further includes second adjusting unit 160 or 180 which are connected with the driving power line 30 in order to adjust voltages between the third end 110-3 and the first end 110-1 of the BJT 113 not higher than a second standard voltage. The second adjusting unit 160 of the present disclosure consists of one more diodes. The second adjusting unit 180 includes component other than diode.

In order to distinguish the second adjusting unit 160 from the second adjusting unit 180, the second adjusting 160 consisting of diodes is named as a second diode unit 160 in following description of the present disclosure.

When the present disclosure utilizes the second diode unit 160 consisting of diodes to adjust the voltage between the third end 100-3 and the first end 110-1, one end of the second diode unit, which consists of diodes, is connected with the third end 110-3 and another end of the second diode unit is connected with the driving power line 30. The second diode unit 160 is in parallel to the driving power line 30.

The third end 110-3 is the collector of the BJT 113. The first end 110-1 is the emitter of the BJT 110. The second standard voltage and the first standard voltage are set according to practical application of the low noise amplifier 100, according to the absolution maximum rating voltage of the BJT 113, or according other situations. The number or structure of diodes in the second diode unit 160 can be adjusted according to the second standard voltage.

The following description illustrates the method of the present disclosure about how to restrict the voltages between collector 110-3 and the emitter 110-1 of the second diode unit 160 within the second standard voltage on the basis of the second diode unit 160 shown in FIG. 2.

First, based on the peak value, when the voltage of the collector 110-3 higher 2 V than the driving power, the second diode unit 160 of the present disclosure has bias voltage. Therefore, by utilizing the above-mentioned second diode unit 160, current is discharged from the collector 110-3 to the driving power line. As a result, the voltage difference between the voltage of collector 110-3 and the driving voltage V_{DD} is restricted within 2 V (i.e. the second standard voltage).

If the voltage difference between the voltage of collector 110-3 and the driving voltage V_{DD} is restricted within 2 V, the voltage difference between the voltage of collector 110-3 and the emitter 110-1 is also restricted within V_{DD}+2 V. In other words, by utilizing the restricting function implement by the second diode unit 160, the voltage difference between the voltage of collector 110-3 and the emitter 110-1 is under the summed voltage of driving voltage and the second standard voltage (V_{DD}+2 V).

Therefore, the low noise amplifier 100 of the present disclosure further includes the second diode unit 160 which can restrict or adjust the voltage between the collector 110-3 and the emitter 110-1. That is, the low noise amplifier 100 of the present disclosure not only can adjust the voltage between the emitter 110-1 and the base 110-2 and can adjust the voltage between the collector 110-3 and the emitter 110-1, but also can restrict these two kinds of voltages within the absolute maximum rating voltage. As a result, the safety is enhanced and the bipolar junction transistor 113 or the low noise amplifier 100 can be precise driven.

In other embodiments, the low noise amplifier 100 of the present disclosure may further include a third diode unit 170 which can adjust the voltage of the input signal under a third standard voltage. The third diode unit 170 of the present disclosure converts the above-mentioned high-power input signal to a voltage within a prescribed range before the input signal having high power passes through the step of the first diode unit 150 being adjusted.

FIG. 2 illustrates an example in which the third diode unit 170 of the present disclosure is constructed of two back-to-back diodes. Based on the back-to-back structure shown in FIG. 2, the third embodiment of the present disclosure restricts the inputting under the third standard voltage.

In the back-to-back diodes, if applying an input signal having a voltage higher than +1 V, the diode 173 (the left diode) on the left side is biased in the forward direction, and the diode 171 (the right diode) on the right side is biased in reverse direction.

Therefore, the current of the input signal is discharged to the ground GND through the left side diode 173 which is forward biased. Thus, the voltage applied to the first diode unit 150 can be prevented from being higher +1 V than a clamping voltage.

In contrast, if applying an input signal having a voltage lower than −1 V, the left side diode 173 in the back-to-back diodes is reverse biased, and the right side diode 171 is forward biased.

Therefore, the current of the input signal is discharged to the ground GND through the right side diode 171 which is forward biased. Thus, the voltage applied to the first diode unit 150 can be prevented from being lower +1 V than a clamping voltage.

In addition, of applying a voltage being between −1 V and +1 V, diodes in the back-to-back structure are both reverse biased. The voltage applied to the first diode is between −1 V and +1 V.

As described above, if the low noise amplifier 100 of the present disclosure further includes the third diode unit 170, only the input signal that is restricted in the specified voltage range is applied to the first diode unit 150. Therefore, the power or voltages of the input signal required by the first diode 150 is reduced to within a predetermined range, so that the first diode 150 becomes lighter or minor.

Moreover, as described above, the third diode unit 170 of the present disclosure uses its own characteristics to restrict the overvoltage applied to the input line 10 within a predetermined range. In the meanwhile, the ESD diode disposed in the internal circuits of the low noise amplifier 100 is protected.

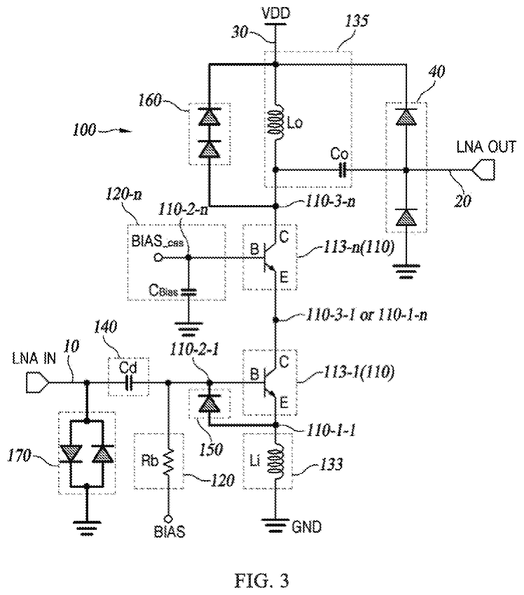

FIG. 3 illustrates a circuit diagram of a low noise amplifier 100 of the present disclosure which utilizes a diode for adjust the voltage applied to the terminals of the BJT 113. As shown in FIG. 3, the low noise amplifier 100 of the present disclosure consists of a plurality of cascaded BJTs 113.

As shown in FIG. 3, the low noise amplifier 100 of the present disclosure can include a plurality of BJTs 113-1 to 113-n connected (cascaded) to each other, the bias unit 120, the impedance matching unit 130, the blocking capacitor 140, and the first diode unit 150.

In the above-mentioned structure, the bias unit 120, the impedance matching unit 130, and the blocking capacitor 140 perform the same functions as the amplifier having single BJTs 113 amplifier. Therefore, the following details of the present disclosure will illustrate the low noise amplifier 100 includes cascaded amplifiers.

The plurality of the cascaded BJTs 113-1 to 113-n includes an input BJT 113-1 connected with input line 10 and an output BJT 113-n. An emitter 110-1-n is connected with a collector 110-3-1 of the BJT.

FIG. 3 illustrates two BJT 113-1 and 113-n as an example of cascaded BJTs. The low noise amplifier 100 is implemented by the plurality of BJTs 113-2 to 113-n of the present disclosure according to amplifying target or noise figures.

A second bias unit 120-n which is connected with a base 110-2-n of the output BJT 113-n performs biasing functions. A capacitor C_{Bias} is a bypass capacitor utilized to perform alternating current (AC) ground to the base 110-2-n of the BJT 113-n.

When the BJT 113 of the present disclosure consists of cascaded BJTs, the first diode unit 150 is disposed between the BJT 113-1 to 113-n and the input line 10. That is, the first diode unit 150 is disposed between an emitter 110-1-1 and a base 110-2-1 for adjusting the voltage between the emitter 110-1-1 and the base 110-2-1 not higher than the first standard voltage.

According to above-mentioned embodiment, the first standard voltage can be adjusted according to practical application, absolute maximum rating voltages of BJTs, etc. The number and the structure of the first diode 150 can be adjusted according to the voltage potential of the first standard voltage.

According to embodiment having the cascaded BJTs shown in FIG. 3, the present disclosure further includes the second diode unit 160. The second diode unit 160 is connected with the driving power line 30 for adjusting the voltage between a collector 110-3-n of the BJT 113-n and the emitter 110-1-n of the BJT 113-1 not higher than the second standard voltage.

On the basis of the cascade BJTs shown in FIG. 3, a node corresponding to the collector 110-3-1 of the input BJT 113-1 or a node corresponding to the emitter 110-1-n of the output BJT 113-n has lower impedance. Therefore, the voltages between the collector 110-3-1 of the input BJT 113-1 and the emitter 110-1-n of the output BJT 113-n do not exceed the absolute maximum rating voltage.

Therefore, as shown in FIG. 3, the second diode unit 160 is connected to the driving power line 30 for restricting the voltages between the driving power V_{DD} and the collector 110-3-n of the BJT 113-n.

As shown in FIG. 3, one end of the second diode unit 160 is connected to the driving power line 30 and another end of the second diode unit 160 is connected to the collector 110-3-n of the output BJT 113-n. To conclude, the second diode unit 160 parallel to the driving power line 30.

As described above, the second standard voltage can be changed. The number, structure of the diodes of the second diode 160 can also be changed according to the voltage potential of the second standard voltage.

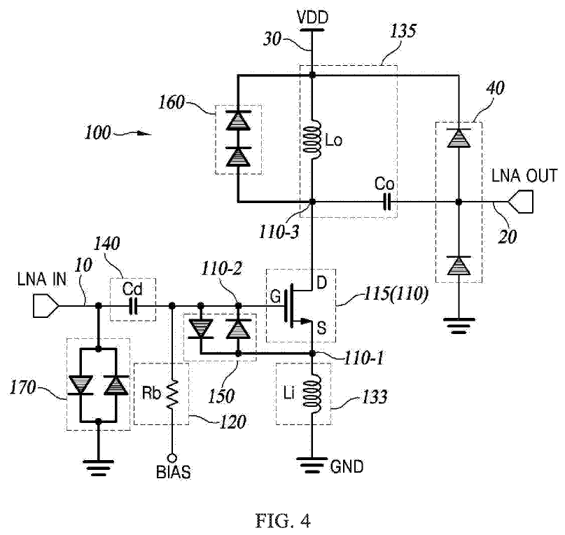

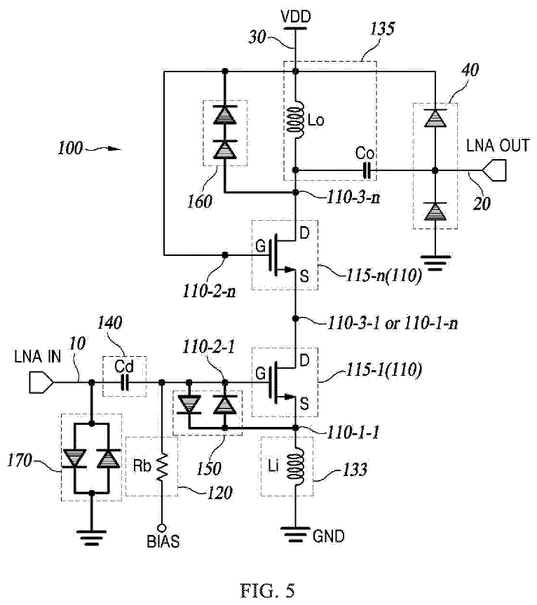

FIG. 4 and FIG. 5 illustrate a low noise amplifier 100 of the second embodiment of the present disclosure which adjusts voltages applied to the FET 115 by utilizing diodes. As shown in FIG. 4 and FIG. 5, in the second embodiment, the transistor 110 of the low noise amplifier of the present disclosure is FET 115.

As shown in FIG. 4, the low noise amplifier 100 of the present disclosure includes the FET 115, the bias unit 120, the impedance matching unit 130, the blocking capacitor, and a first diode unit 150.

First, the FET 115 of the present disclosure is connected to the input line 10 for implementing amplifying functions. Therefore, input signals inputted through the input line 10 are amplified by the low noise amplifier 100. The amplified signals are outputted through the outputting line 20.

A source of the FET 115 is connected to the ground GND. A gate of the FET 115 is connected to the input line 10. A drain of the FET 115 is connected to the outputting line 20.

The FET 115 in FIG. 4 is a common-source (CS) amplifier. However, if the amplifying functions can be achieved, the FET 115 can be a common-gate (CG) amplifier or a common-drain (CD) amplifier.

In the FET 115 of the present disclosure as shown in FIG. 4, the gate 110-2 (a second terminal) is connected to the input line 10 of the low noise amplifier 100, the drain 110-3 (a third terminal) is connected to the driving power line 30 and the outputting line 20. A source 110-1 (a first terminal) is connected to the ground GND. The driving power line 30 is utilized to supply driving powers to the low noise amplifier 100.

The bias unit 120, the impedance matching unit 130, and the blocking capacitor Cd as shown in FIG. 4 have the same functions as the low noise amplifier 100 utilizing the BJT 113. Therefore, a detailed of the above structure will be omitted, and following descriptions illustrates the low noise amplifier 100 of the present disclosure having the FET 115 as the transistor 110.

The first diode unit 150 is disposed between the first terminal 110-1 (source) and the second terminal 110-2 (gate). A voltage between the source 110-1 and the gate 110-2 is adjusted to nit higher than the first standard voltage.

When the first reference voltage corresponds to the absolute maximum rating voltage of the FET 115, as shown in FIG. 4, the first diode unit 150 of the present disclosure may include two diodes connected back-to-back.

The first diode unit 150 in a back-to-back structure has a difference from the BJT 113 described above. This difference is the different characteristics of the BJT 113 and the FET 115, particularly, the difference voltage between of the first terminal 110-1 and the second terminal 110-2 and absolute maximum rating voltage of the FET 115.

More particular, viewing from the aspect of peak voltage, the absolute maximum rating voltage of the BJT 113 is 1 V, the absolute maximum rating voltage of the FET 115 is between +1 V to −1 V. As shown in FIG. 4, the first diode unit 150 preferably has a back-to-back structure to conform to the maximum constant voltage characteristics of the FET 115.

The second adjusting unit 160, 180 of the present disclosure work in the similar functions as same as the BJT 113 amplifier described above. The second adjusting unit 160 or the second adjusting unit 180 is connected to the driving power line 30, thus the voltages between the drain 110-3 o and the source 110-1 of the FET 115 are adjusted not higher than the second standard voltage.

When the second adjusting unit 160 consists more than one diodes, the second adjusting unit 160 is the second diode unit 160. The second standard voltage corresponds to the absolute maximum rating voltage of the FET 115 (taking e peak value as 7.35 V as an example). Please refer to FIG. 4, the second diode unit 160 of the present disclosure has two diodes connected in series so that the voltage between the drain 110-3 and the source 110-1 is restricted under the value 7.35 V.

The third diode unit 170 of the present disclosure has a back-to-back structure as the BJT 113 amplifier described above. The third diode unit 170 is connected with the input line 10 in order to restrict the voltage of the input signal within a predetermined range (third standard voltage) and in order to protect the ESD. For example, the third diode unit 170 of the present disclosure can restrict the voltage applied to the gate 110-2 of the FET 115 between −1 V to +1 V.

According to the embodiments, the FET 115 amplifier may be a cascaded FETs structure as the cascaded BJT 113-1 to 113-n.

As shown in FIG. 5, the plurality of cascaded FETs 115-1 to 115-n include an input FET 115-1 connected to the input line 10 and an output FET 115-n. a source 110-1-n of the output FET 115-n is connected to the drain 110-3-1 of the input FET 115-1.

FIG. 5 illustrates an embodiment which includes the FET 115-1 cascaded to the FET 115-n. However, a plurality of FETs 115-1 to 115-n may be used to achieve target amplifier and noise figure.

As described above, when the FET 115 has cascaded FETs, the first diode unit 150 is disposed between the gate 110-2-1 of the input FET 115-1 and the source 110-1-1 of the input FET 115-1. The voltage between the gate 110-2-1 and the source 110-1-1 is adjusted not higher than the first reference voltage.

The second diode unit 160 of the present disclosure is connected to the driving power line 30. In the plurality of FETs 115-1 to 115-n, the voltages between the drain 110-3-n of the output FET 115-n and the source 110-1-n of the output FET 115-n is below the second standard voltage.

On the other hand, based on the cascaded structure shown in FIG. 5, a node corresponds to the drain terminal 110-3-1 of the input FET 115-1 or the source terminal 110-1-n of the output FET 115-n has a lower impedance. The voltage between the drain 110-3-1 of the input FET 115-1 and the source 110-1-1 of the input FET 115-1 does not exceed the absolute maximum rating voltage.

Therefore, as shown in FIG. 5, even only the second diode unit 160 connected to the driving power line 30 is used to restrict output voltage of the drain 110-3-n of the FET 115-n and the driving power V_{DD}. The maximum voltage of the cascaded FETs 115-1 to 115-n can also be satisfied.

As described above, the present disclosure is not limited to the low noise amplifier 100 constructed by the BJT 113. The low noise amplifier 100 may also be composed of the single FET 115 or the cascade FETs 115-1 to 115-n. Extra diodes can be added to adjust the voltage applied between the terminals of the FET 115 or to restrict corresponding voltages within the absolute maximum rating voltage. Therefore, the technical characteristics of the present disclosure which adjusts voltage by diodes can be applied to wider fields.

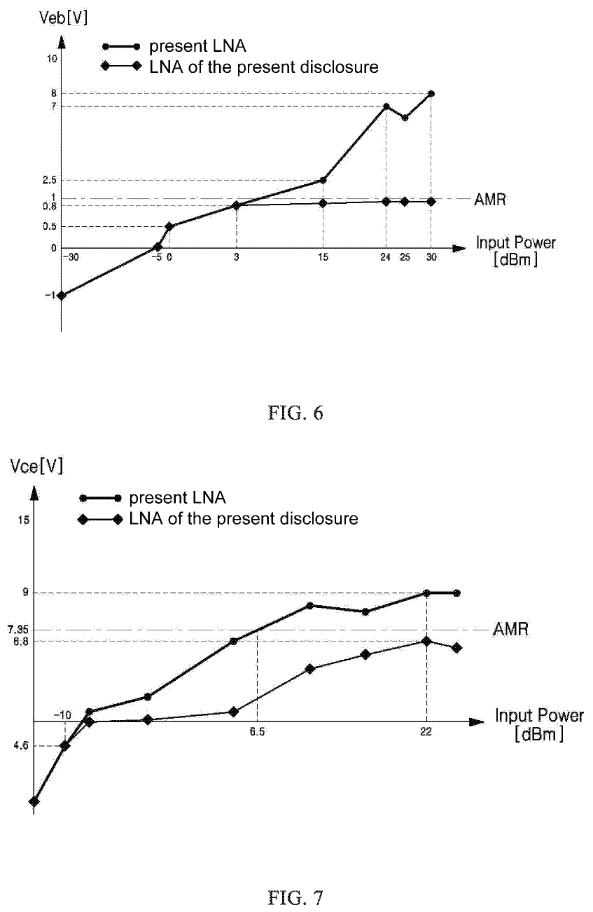

FIG. 6 illustrates simulation results regarding the power of the input signal of the conventional low noise amplifier. FIG. 7 illustrates simulation results regarding the power of the input signal of the BJT 113 of low noise amplifier 100 shown in FIG. 2. Please refer to FIG. 6 and FIG. 7 respectively illustrate simulation results when input voltage between the first terminal 110-1 and the second terminal 110-2 is adjust below a standard voltage(absolute maximum rating voltage) of the present amplifier and simulation results when input voltage between the third terminal 110-3 and the first terminal 110-1 is adjust below a standard voltage (absolute maximum rating voltage) of the low noise amplifier of the present disclosure.

FIG. 6 illustrates a simulation result regarding the voltage between the first terminal 110-1 and the second terminal 110-2 according to the input signal. The horizontal axis of FIG. 6 represents the power of the input signal, and the vertical axis represents the voltage potential between the first terminal 110-1 and the second terminal 110-2, i.e. the voltage between the emitter 110-1 and base 110-2. The simulation experiment was performed by setting the unit of the input signal in dBm. The voltage between the emitter 110-1 and the base 110-2 was set to a peak value to perform a simulation experiment.

As shown in FIG. 6, before the input signals of the conventional low noise amplifier and the low noise amplifier 100 of the present disclosure reach 3 dBm, the rated voltages AMR fall in 1 V. When the input signals reach about 3 dBm or more, the overvoltage, on the basis of the absolute maximum rating voltage AMR, between the emitter and the base continuously increases accompanying with the powers of input signals.

In contrast, the improved low noise amplifier 100 of the present disclosure maintains the voltage between the emitter 110-1 and the base 110-2 within the absolute maximum rating voltage AMR even if the power of the input signal increases.

FIG. 7 illustrates the simulation result regarding to the input signal and the voltage between the third terminal 110-3 and the first terminal 110-1.

The simulation experiment shown in FIG. 7 also sets the unit of the input signal to dBm and sets the voltage between the collector 110-3 and the emitter 110-1 to a peak value. Please refer to FIG. 7. Before the power of the input signal reaches 6.5 dBm, the voltages between collector 110-3 and emitter 110-1 of the conventional low noise amplifier increase within the range of the absolute maximum rating voltage AMR. The voltage between collector 110-3 and emitter 110-1 of the low noise amplifier 100 of the present disclosure also increases within the range of the absolute maximum rating voltage AMR.

When the power of the input signal power is set at about 6.5 dBm, the voltages between the collector and the emitter of the two low noise amplifiers are different. In the conventional low noise amplifier, the voltage between two terminals exceeds the absolute maximum rating voltage 7.35 V. In contrast, the voltage between the two terminals remain in 7.35 [V] of the low noise amplifier of the present disclosure.

Even if the applied power of input signal is increased, the voltage between two terminals in the low noise amplifier of the present disclosure still remains within the absolute maximum rating voltage.

From the simulation results shown in FIG. 6 and FIG. 7, it is obvious that the low noise amplifier 100 of the present disclosure can apply the voltage, restricted within he absolute maximum rating voltage, on the emitter 110-1 and the base 110-2 when a high power of the input signal is applied.

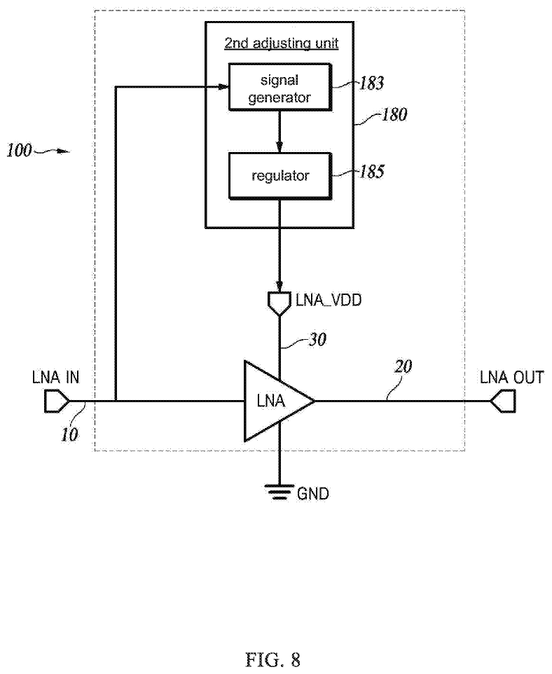

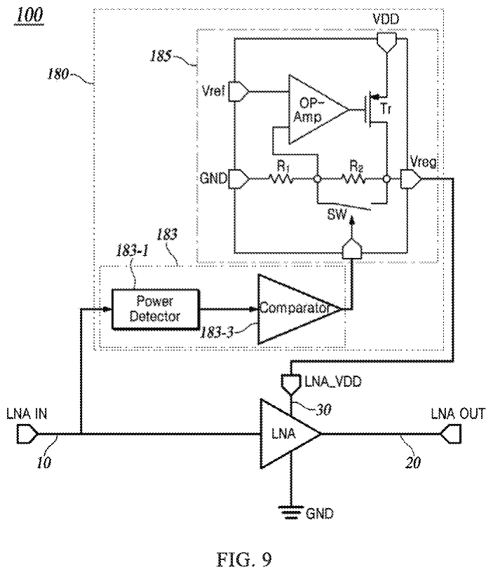

FIG. 8 and FIG. 9 illustrate a low noise simplifier 100 of a third embodiment of the present disclosure. The low noise simplifier 100 of the third embodiment consists of electronic components other than diodes for adjusting voltages applied to the transistor 110.

Hereinafter, with reference to FIG. 8 and FIG. 9, the technical features of the present disclosure of adjusting the voltage applied between the third terminal 110-3 of the transistor 110 and the first terminal 110-1 f the transistor 110 by utilizing the second adjusting unit 180 will be described in detail.

As shown in FIG. 8, the second adjusting unit 180 of the present disclosure is connected between the input line 10 and the driving power line 30. The second adjusting unit 180 applies different powers to the driving power line 30 according to the voltage potentials of the signals (input signals) input through the input line 10.

In FIG. 8, the second adjusting unit 180 of the present disclosure is represented by a function. FIG. 8 does not illustrate the structure of the external driving power source (i.e. voltage VDD shown in FIG. 9) applied to the second adjusting unit 180. The second adjusting unit 180 converts the applied driving power source (voltage VDD of FIG. 9) to different voltage potentials according to the voltage potential of the input signal and applies the converted voltage to the driving power line 30.

The second adjusting unit 180 applies different voltages to the driving line 30 for adjusting the voltage between the third terminal 110-3 and the first terminal 110-1 to be equal to or lower than the second reference voltage, that is, the two terminals 110-3. The voltage adjust between 110-1 is below the second reference voltage.

The second adjusting unit 180 of the present disclosure converts the driving power source to different voltage potentials according to the voltage potential (power) of the input signal. If applying the voltage through the driving power line 30, the voltages applied to the low noise amplifier or the transistor the can be floated adjusted regardless the voltage potential of the RF signals.

The second adjusting unit 180 of the present disclosure adjusts the externally applied driving power for adjusting or restricting voltage between the third terminal 110-3 and the first terminal 110-1 of the transistor 110 to a target voltage (i.e. the second standard voltage). This is different from the first embodiment described above which utilizing diodes to adjust voltage.

According to the embodiment as shown in FIG. 8, the second adjusting unit 180 of the present disclosure may include a signal generator 183 and a voltage regulator 185. As described above, the transistor 110 may include the BJT 113 or the FET 115. The bias unit 120, the impedance matching unit 130, and the blocking capacitor 140 also perform the functions as described above. Therefore, following illustration focuses on the structure and functions of the second adjusting unit 180 of the low noise amplifier 100 of the present disclosure.

The second adjusting unit 180 of the present disclosure can be implemented by various electronic components if the voltage between the third terminal 110-3 and the first terminal 10-1 can be adjusted below the second standard voltage.

However, in order to implement the driving voltage adjust functions to ensure the effectiveness of the driving when the input signal has higher voltage potential, the second adjusting unit 180 of the present disclosure includes a component (such as signal generator) for determining whether the input signal reaches a predetermined voltage potential and a component (such as voltage regulator) for applying a relatively low voltage potential to the driving power line 30 when the input signal reaches a predetermined voltage potential.

First, the signal generator 183 of the present disclosure is connected to the input line 10 of the low noise amplifier 100. If the voltage potential of the input signal is higher than a predetermined detecting voltage, the signal generator 183 outputs an enable signal is outputted.

The predetermined detecting voltage means the voltage potential of the input signal should be prevent from being higher than the absolute maximum rating voltage. The detecting voltage can be set according to the intention of the user, the designer, or the absolute maximum rating voltage of the transistor 110.

The signal generator 183 generates the enable signal based on whether or not the input signal reaches the detecting voltage. The enable signal can be generated according to various elements or conditions.

For example, when the voltage potential of the signal is equal to or higher than the potential of the detecting voltage, the signal generator 183 of the present disclosure can output “1” as an enable signal. If the voltage potential of the signal does not exceed the potential of the detecting voltage, the signal generator 183 of the present disclosure can output “0” as a disable signal or does not output any signal.

On the other hand, the output signal is an alternating current (AC) signal having a specific frequency. The voltage potential of the output signal is frequently changes. Therefore, in order to accurately compare the potential of the input single and the detecting voltage, a method for maintaining the input signal or a method for specifying the input time of the input signal is required.

Therefore, as shown in FIG. 9, the signal generator 183 of the present disclosure includes a signal detector (such as a power detector) 183-1 connected to the input line 10 and a comparator 183-3. The signal detector is utilized to detect the voltage potential of the input signal. The comparator 183-3 compares the input signal with the detecting voltage, and outputs an enable signal when the voltage potential of the input level reaches the potential of the detecting voltage.

The signal detector 183-1 of the present disclosure performs voltage potential comparison between the input signal having alternating current waveforms and the detecting voltage. The signal detector 183-1 can include an envelope detector, peak detector, and other components. The comparator 183-3 of the present disclosure may include Schmitt trigger and other components.

As shown in FIG. 8 and FIG. 9, an input end of the regulator 185 of the present disclosure is coupled to the signal generator 183. An output end of the regulator 185 is coupled to the driving power line 30 for applying voltages having different potentials to the driving power line 30 regarding to the enable signal outputted from at the signal generator 183.

The regulator 185 of the present disclosure is a component that can output voltages having different potentials of according to the enable signal. Preferably, because a voltage difference between the input signal and the output signal (i.e. the voltage difference between VDD and Vreg as shown in FIG. 9) is reduced, an low energy loss and a low drop output (LDO) can be achieved by utilizing the regulator 185.

By the performance of the regulator 185 of the present disclosure, the voltages applied to the regulator 185 can be adjusted by regulator 185 itself or by other methods.

One of the other methods of adjusting the voltages applied to the regulator 185 is utilizing switch in parallel with impedance (i.e. one of the resistances of R1 and R2 as shown in FIG. 9). The impedance is connected to the output end of the regulator 185.

First, when the voltage potential has not exceed the detecting voltage, when a disable signal that does not detect, or when the enable signal has not been outputted, the regulator 185 of the present disclosure turns off a switch SW so that the voltage applied to the source terminal 110-1 of the transistor Tr is transmitted to the driving power line 30 of the low noise amplifier 100.

In contrast, when the enable signal is outputted, the voltage regulator 185 of the present disclosure turns the switch SW on so that only the voltage applied to R1 is transmitted to the driving power line 30 of the low noise amplifier 100.

When the switch SW is turned off, the voltage applied to the driving power line 30 corresponds to a high voltage potential. When the switch is turned on, the voltage applied to the driving power line 30 corresponds to a low voltage potential. Therefore, the switching action of the switch SW make the voltage potential applied to the driving power line 30 become different.

The technical feature of the present disclosure is that the driving power is adjusted by utilizing the second adjusting unit 180. Thus, the voltage between the third terminal 110-3 and the first terminal 110-1 of the transistor 110 is restricted within the second standard voltage. The voltage regulator 185 of the present disclosure applies different voltage potentials to the driving power line 30 and converts the voltage between the third terminal 110-3 and the first terminal 110-1 to be correspondingly lower than the second standard voltage.

The embodiments, although not shown, the second adjusting unit 180 of the low noise amplifier 100 of the present disclosure may further include the first diode unit 150 or the third diode unit 170 described above. In the structure of this embodiment, the voltage between a terminal 110-1 (emitter or source terminal) and a second terminal 110-2 (base or gate terminal) is adjusted to below a predetermined level or adjust or below an absolute maximum rating voltage.

If the present disclosure further includes a second adjusting unit 180 composed of a component other than the diode, the driving power applied to the low noise amplifier 100 may be changed or restricted so that a voltage having lower potential is applied between the third terminal 110-3 and the first terminal 110-1.

Therefore, the present disclosure can satisfy the transistor requiring high-demand specifications transistor or requiring a lower absolute maximum rating voltage. As a result, wider applicability is ensured.

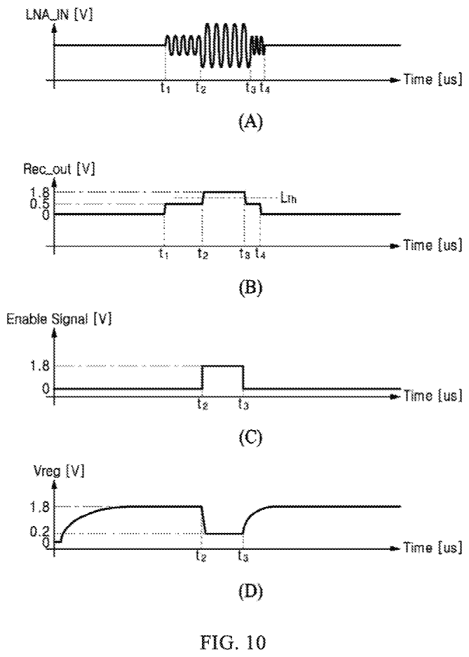

FIG. 10 is a simulation result of the second adjusting unit 180 shown in FIG. 8 and FIG. 9. Hereinafter, the functions of the second adjusting unit 180 composed of component other than the diode will be described in detail accompanying with FIG. 10.

The simulation result shown in FIG. 10 is performed in the basis of the second adjusting unit 180 including the signal generator 183 and the voltage regulator 185. A signal detector 183-1 includes an envelope detector and a comparator, which may be a Schmitt trigger. The regulator 185 is a low dropout regulator.

Further, the voltage is measured based on the peak value. The Schmitt trigger 183-3 output the reference voltage potential (detecting voltage LTh) for the enable signal. The voltage outputted by the Schmitt trigger 183-3 falls in the range between 0.55 V and 0.65V. The simulation is performed in above-mentioned conditions

First, a portion (A) of FIG. 10 shows an input signal LNA_IN inputted to the signal generator 183 through the input line 10. In the portion (A) shown in FIG. 10, a voltage potential of input signal in duration t1-t2 is relatively lower than a voltage potential of input signal in duration t3-t4.

A portion (B) as shown FIG. 10 shows the detecting result of envelopes when mixing input signals with different voltage potentials according to different durations by utilizing the envelope detector 183-1. In the portion (B) shown in FIG. 10, an envelope being 0.5 V is applied to the input signals in the duration t1-t2 and the duration t3-t4. An envelope being 1.8 V is applied to the input signals in the duration t2-t3 interval is detected as 1.8. The input signals of the remaining durations are applied 0 V as envelope.

The detecting voltage L_{Th} is the standard for whether to output the enable signal or not. Only input signal in the duration t2-t3 has voltage potential being higher than the detecting voltage LTh.

A portion (C) of FIG. 10 represents the enable signal outputted by the Schmitt trigger 183-3. As described above, only the input signal in the duration t2-t3 has a voltage potential being higher than the detecting voltage. Therefore, the Schmitt trigger 183-3 starts outputting the enable signal after the input signal at interval t2 reaches 0.65 V and ends to output the enable signal after the input signal at interval t3 is below 0.55V.

The enable signal as shown in drawings is 1.8 V. However, the voltage potential of the enable signal can be adjusted according to various applications.

A portion (D) of FIG. 10 shows different voltages applied to the driving power line 30 by the low dropout regulator 185. As shown in portion (C) of FIG. 10, the enable signal is outputted in the duration t2-t3. Therefore, in the remaining durations, the total voltage applied to the impedance (R1 and R2 as shown in FIG. 9) being 1.3 V is transmitted to the driving power line 30 of the low noise amplifier 100. In the duration t2-t3 when the enable signal is outputted, a relatively low voltage 0.2 V is applied to the driving power line 30.

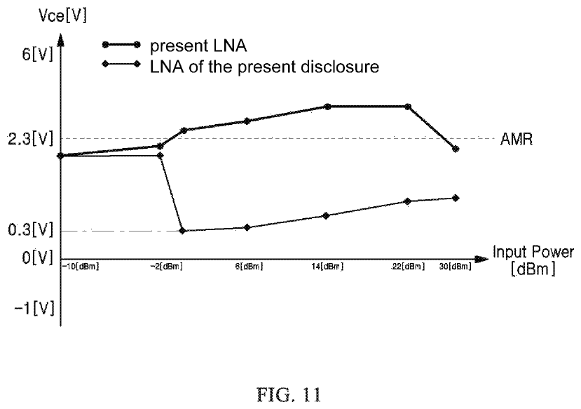

FIG. 11 is a simulation result of the voltage applied to the BJT 113 of the low noise amplifier 100 shown as shown in FIG. 8 and FIG. 9. Hereinafter, accompanying with FIG. 11, the effect of the present disclosure which can obtain the maximum performance improvement by utilizing the second adjusting unit 180 to maximize the rating value of the low noise amplifier 100

The horizontal axis of FIG. 11 represents the power of the input signal, and the vertical axis represents the voltage of the transistor 110, that is, voltage between the third terminal 110-3 (collector) and the first terminal 110-1 (emitter) of the BJT 113. The unit of the input signal in simulation result is dBm. The voltage between the collector 110-3 and the emitter 110-1 was set to a peak value to perform the simulation.

As shown in FIG. 11, the current low noise amplifier does not include an additional devices or components to prevent or restrict high input power. Therefore, as the input power increases, the voltage between the collector and the emitter may exceed the absolute maximum rating voltage AMR (2.3 V) if the power of the input signal increases.

The low noise amplifier 100 of the present disclosure includes a second adjustment unit 180 that restricts or adjusts the voltage VDD. Even if the power of the input signal continues to increase, the voltage between the collector 110-3 and the emitter 110-1 can also be restricted below the absolute maximum rating voltage AMR.

The above description only illustrates the technical idea of the embodiments of the present disclosure. Modifications and variations can be made by a skilled person in the art without departing from the aspect and scope of the present disclosure. Therefore, the present embodiment is not intended to limit the technical idea of the embodiments of the present disclosure, but is used to explain the technical idea of the embodiments of the present disclosure. The scope of the technical idea of the present embodiment is not limited to these embodiments. The scope of the present invention should be construed in accordance with the following claims, and all technical ideas within the scope of the invention should be included in the scope of the embodiments of the present disclosure.

What is claimed is:

1. A low noise amplifier with improved absolute maximum rating performance, comprising:
at least one transistor utilized to amplify a input signal externally input through an input line of the low noise amplifier;
a bias unit connected to the input line and configured to set a driving condition of the transistor;
impedance matching unit configured to match an impedance of the low noise amplifier;
a blocking capacitor connected to the input line and configured to block a direct current of the input signal; and
a first diode unit connected to a first end of the transistor and a second end of the transistor, the first diode unit configured to adjust a voltage between the first end of the transistor and the second end of the transistor under a first standard voltage.

2. The low noise amplifier with improved absolute maximum rating performance according to claim 1, wherein the transistor is a field-effect transistor; the first standard voltage is a maximum rating voltage between the first end of the transistor and the second end of the transistor; the first diode unit comprises two diodes arranged back-to-back.

3. The low noise amplifier with improved absolute maximum rating performance according to claim 1 further comprising a second adjusting unit connected to a driving power line of the low noise amplifier; wherein the second adjusting unit is configured to adjust a voltage between the first end of the transistor and a third end of the transistor under a second standard voltage.

4. The low noise amplifier with improved absolute maximum rating performance according to claim 3, wherein the second adjusting unit consists of the driving power line in parallel with more than one transistors.

5. The low noise amplifier with improved absolute maximum rating performance according to claim 3, wherein
the second adjusting unit is connected between the driving power line and the signal line, and the second adjusting unit is configured to switch a driving power of the low noise amplifier to different voltages according to voltage of the input signal, wherein the driving power is applied on the driving power line;
the different voltages are utilized to adjust the voltage between the first end of the transistor and the third end of the transistor below the second standard voltage.

6. The low noise amplifier with improved absolute maximum rating performance according to claim 5, wherein the second adjusting unit comprises:
a signal generator connected with the input line and configure to output an enable signal in response to a voltage of the input signal being higher than a predetermined detecting voltage; and
a voltage regulator having an input end and an output end, where the input end of the voltage regulator is connected with the signal generator, the output end of the voltage regulator is connected with the driving power line for determining whether the enable signal is generated, wherein the voltage regulator is utilized to transfer the driving power into the different voltages applied on the driving power line.

7. The low noise amplifier with improved absolute maximum rating performance according to claim 6, wherein the signal generator comprises:
a signal detector connected with the input line and configured to detect a voltage of the input signal;
a comparator connected between the signal detector and the voltage regulator and configured to compare the voltage of the input signal with the predetermined detecting signal, and configure to output the enable signal in response to the voltage of the input signal being higher than the predetermined detecting signal;
wherein the voltage regulator switches the driving power to a low voltage of the different voltages in response to the enable signal is output, the voltage regulator switches the driving power to a high voltage of the different voltages in response to the enable signal is not output.

8. The low noise amplifier with improved absolute maximum rating performance according to claim 6, wherein the voltage regulator is a low-dropout regulator.

9. The low noise amplifier with improved absolute maximum rating performance according to claim 1 further comprising a third diode unit, wherein the third diode unit is connected with the input line for adjusting the voltage of the input signal below a third standard voltage.

10. The low noise amplifier with improved absolute maximum rating performance according to claim 9, wherein the third diode unit includes two diodes arranged back-to back.

11. The low noise amplifier with improved absolute maximum rating performance according to claim 1, wherein
the transistors comprises an input transistor connected with the input line and an output transistor connected with the driving power line of the low noise amplifier, sources of the plurality of the transistors are coupled and gates of the plurality of the transistors are coupled;
wherein the first diode unit is connected between a first end of the input transistor and a second end of the output transistor.

12. The low noise amplifier with improved absolute maximum rating performance according to claim 3, wherein
the transistors comprises an input transistor connected with the input line and an output transistor connected with the driving power line of the low noise amplifier, wherein the transistor consist of a plurality of transistors, sources of the plurality of the transistors are coupled and gates of the plurality of the transistors are coupled;
the second adjusting unit is utilized to adjust a voltage between a third end of the output transistor and a first end of the output transistor below the second standard voltage.
